(19) United States
(12) Patent Application Publication
(10) Pub. No.: US 2022/0293884 A1
(43) Pub. Date: Sep. 15, 2022

(54) Encapsulated Electronic Device with Improved Protective Barrier Layer and Method of Manufacture Thereof

(71) Applicant: SDK New Materials, Inc., Santa Clara, CA (US)

(72) Inventors: Wenming Li, Milpitas, CA (US); Jiaming Hua, Taicang (CN); Xingbao Zhou, Taicang (CN); Qiujun Pan, Redwood City, CA (US); Chuang Jin, Taicang (CN)

(21) Appl. No.: 17/202,242

(22) Filed: Mar. 15, 2021

(51) Int. Cl. H01L 51/52; H01L 51/00; H01L 51/56

(52) U.S. Cl. CPC H01L 51/5253; H01L 51/0097; H01L 51/56; H01L 2251/5338

(57) ABSTRACT

Embodiments of a thin film protective barrier for an encapsulated electronic device is disclosed. The barrier is applied as a thin film coating onto a moisture-sensitive microelectronic device, such as an OLED. A density of the barrier is varied during fabrication, allowing the barrier to flex in applications that demand that the encapsulated electronic device be flexible, while providing a highly-resistant barrier to moisture, oxygen and other contaminants.

### BACKGROUND

### I. Field of Use

The present application relates to the field of thin film encapsulation and more particularly to the use of thin film encapsulation to protect sensitive thin film structures.

### II. Description of the Related Art

Many devices, such as OLED, LED, thin film solar cell, medical devices etc. are extremely sensitive to certain contaminants, such as oxygen, moisture, and chemicals, sometimes even during the manufacturing process. Such contaminants can quickly cause degradation in these types of devices, and so they are typically encapsulated in order to prevent such degradation.

In order to combat the deleterious effects of contaminants, various types of encapsulation techniques have been developed. For example, U.S. patent publication 20140060648A1, entitled “Inorganic multilayer stack and methods and compositions relating thereto” and U.S. Pat. No. 7,648,925, entitled “Multilayer barrier stacks and methods of making multilayer barrier stacks” each describe how contaminant-sensitive devices can be protected by depositing “barrier stacks” adjacent to one or both sides of a device. The barrier stacks typically comprise at least one layer of material, and sometimes two or more layers. A single barrier stack described by the aforementioned references is typically about 100-400 Å thick. The one or more stacks provide a physical barrier to protect devices from contaminants.

The number of barrier stacks needed typically depends on a level of water vapor resistance needed for a particular application. One or two barrier stacks provides sufficient barrier properties for some applications, while three or four barrier stacks are needed for other applications. More stringent applications may require five or more barrier stacks in order to protect a device to which the barrier stacks are affixed.

It is anticipated that OLED devices, such as televisions, will not only continue to grow in size, but also be manufactured on flexible substrates, sometimes referred to as a “web”. Such flexible substrates include polyethylene naphthalate (“PEN”), polyethylene terephthalate (“PET”), as well as others, and may be well-suited for relatively large products that require flexibility and low cost, such as televisions, computer displays, and desktop lighting. Introducing flexible substrates, however, generally requires the use of flexible barrier layers, for example, alternating layers of organic and inorganic material, as described by U.S. Pat. No. 7,767,498 entitled, “Encapsulated devices and method of making” and U.S. Pat. No. 7,648,925 entitled, “Multilayer barrier stacks and methods of making multilayer barrier stacks”. Further complicating the use of flexible substrates such as PET, these flexible substrates have relatively high oxygen permeation rates, for example 1,550 cc/m²/day, and relatively high moisture vapor transmission rates (“WVTR”), for example 272 g/m²/day. As a result, OLED devices using flexible substrates such as PET may begin to degrade immediately during the manufacturing process. In some cases, in order to try to protect OLED devices, an indium tin oxide (ITO) layer may be fabricated onto the substrate, which acts as a partial barrier layer, and a barrier layer be fabricated over the ITO layer, as well as onto the device itself.

Some polymers, such as acrylic foils, work well as moisture barriers for some devices. However, polymers alone typically do not provide enough protection for organic devices such as OLED. Other materials may be needed to work in cooperation with such polymers, or in the alternative, such as one or more inorganic barriers. OLED devices require a moisture barrier layer having a WVTR of at least 10⁻⁶ g/m2/day, while other organic devices may require barrier layers having higher or lower WVTR levels. In some cases, in order to meet these requirements, alternating organic and inorganic layers may be used in order to prevent defects from one layer permeating through to another layer. However, applying alternating layers of organic and inorganic material presents problems during the fabrication process. For example, inorganic layers are normally fabricated in a vacuum environment, while organic layers are not. In a vacuum environment, the organic layer may be easily contaminated and cause a failure of a barrier layer. Additionally, fabricating an organic layer in a vacuum environment may cause chamber contamination, which is difficult to clean.

It would be desirable to protect certain microelectronic devices from the deleterious effects of contaminants, both on rigid and flexible substrates, without using alternating organic and inorganic protection layers.

### SUMMARY

The present application describes embodiments of an encapsulated electronic device comprising a protective barrier layer whose density varies as a function of its thickness. In one embodiment, the encapsulated electronic device comprises a flexible substrate, a microelectronic device fabricated onto a first surface of the flexible substrate, and a protective barrier layer fabricated onto the microelectronic device for preventing contamination of the microelectronic device, the protective barrier layer comprising a density that varies as a function of a thickness of the protective barrier layer.

In another embodiment, a method of manufacturing the encapsulated electronic device comprises fabricating the microelectronic device onto a flexible substrate, and fabricating a protective barrier layer onto the microelectronic device, comprising varying a deposition power density delivered by a deposition power generator over a deposition time while maintaining a constant deposition pressure of a deposition chamber, resulting in the protective barrier layer having a density that varies as a function of its thickness.

In yet another embodiment, a method of manufacturing the encapsulated electronic device comprises fabricating the microelectronic device onto a flexible substrate and fabricating a protective barrier layer onto the microelectronic device, comprising varying a deposition pressure of a deposition chamber over a deposition time while maintaining a constant deposition power density delivered by a deposition power generator, resulting in the protective barrier layer having a density that varies as a function of its thickness.

### BRIEF DESCRIPTION OF THE DRAWINGS

The features, advantages, and objects of the present invention will become more apparent from the detailed description as set forth below, when taken in conjunction with the drawings in which like referenced characters identify correspondingly throughout, and wherein:

FIG. 1 is a microscopic, side view of one embodiment of an article of manufacture fabricated using the teachings herein, shown as an encapsulated electronic device;

FIG. 2 is a microscopic, side view of one embodiment of one of the barrier layers shown in FIG. 1, deposited onto a microelectronic device, also shown in FIG. 1;

FIG. 3 is a graph showing one embodiment of a relationship between a deposition power delivered by thin film deposition equipment as the barrier layer shown in FIG. 2 is fabricated, and a time to fabricate the barrier layer, while the deposition processes occurs at a fixed deposition pressure;

FIG. 4 is a graph showing a relationship between a deposition pressure in a deposition chamber as the barrier layer shown in FIG. 2 is fabricated, and a time to fabricate the barrier layer, while the deposition processes occurs at a fixed deposition power;

FIG. 5 is a graph showing how the density of one or both barrier layers shown in FIG. 1, in one embodiment, varies as a function of its thickness;

FIG. 6 is a microscopic, side view of another embodiment of one of the barrier layers shown in FIG. 1 in an embodiment where the density of a barrier layer varies as a repetition of the density gradients as shown in FIG. 2;

FIG. 7 is a graph showing how a thin film refractive index of one of the barrier layers shown in FIG. 1 varies as a function of its thickness in accordance with FIGS. 5 and 6;

FIG. 8 is a graph showing how the density of one of the barrier layers shown in FIG. 1, in another embodiment, varies as a function of its thickness;

FIG. 9 is a microscopic, side view of another embodiment of one of the barrier layers shown in FIG. 1;

FIG. 10 is block diagram of one embodiment of vapor deposition equipment used for fabricating the barrier layers shown in FIGS. 1, 2, 6 and 9;

FIG. 11 is a flow chart illustrating one embodiment of a method for fabricating an encapsulated microelectronic device as shown in FIG. 1 by thin film equipment as shown in FIG. 10; and

FIG. 12 is a flow chart illustrating another embodiment of a method for fabricating an encapsulated microelectronic device as shown in FIG. 1 by thin film equipment as shown in FIG. 10.

### DETAILED DESCRIPTION

The present application describes embodiments of a method for protecting sensitive organic devices against contaminants during a manufacturing process and an article of manufacture using the method. More specifically, in one embodiment, the article of manufacture comprises a microelectronic device formed onto a rigid or flexible substrate, and then a protective barrier layer is deposited onto the microelectronic device, or both the microelectronic device and the substrate, using thin film deposition techniques. The protective barrier layer prevents moisture and other contaminants from degrading the microelectronic device. The protective barrier layer is specially formed, having a density gradient, i.e., a density that varies, in one embodiment, linearly over the thickness of the protective barrier layer. One advantage of using a barrier layer with a varying density is that it allows the barrier layer and, hence the microelectronic device, to flex in applications where a flexible substrate is used, thus reducing the chance of cracking. Another advantage of using a varying-density barrier layer, especially when multiple layers are used, is that there is no need to alternate deposition methods, as is the case in prior art deposition manufacturing methods that alternate layers of organic and inorganic materials to form a barrier layer.

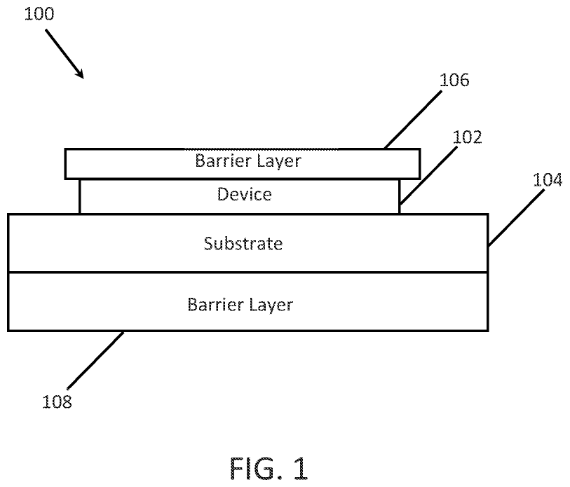

FIG. 1 is a microscopic, side view of one embodiment of an article of manufacture fabricated using the teachings herein, shown as encapsulated electronic device 100. Encapsulated electronic device 100 is an encapsulated microelectronic device, typically a display device, such as an organic light emitting device (OLED), a liquid crystal display (LCD), a light emitting diode (LED), a light emitting polymer (LEP), electronic signage using electrophoretic inks, a electroluminescent device (ED), a phosphorescent device, etc., which is “encapsulated” by protective barrier layers 106 and 108. Encapsulated electronic device 100 may be as small as 10×10 micrometers, with a thickness of about 100 nm to about 600 nm. Millions of encapsulated electronic devices 100 are fabricated together to form a wide variety of consumer products, such as television screens, tablet computer touch screens, smart phone displays, lights, etc. Typically, encapsulated electronic device 100 comprises a number of different layers, as shown. However, it should be understood that the relative sizes and thicknesses of each layer as shown in FIG. 1 may not be shown in correct proportion to the actual sizes and thicknesses of the layers of encapsulated electronic device 100.

Encapsulated electronic device 100, in this embodiment, comprises a microelectronic device 102 deposited onto a rigid or flexible substrate 104, using one or more variations of one or more well-known thin film deposition techniques, such physical vacuum deposition (PVD) techniques, such as RF, pulsed DC or magnetron sputtering, vacuum thermal evaporation (VTE), organic vapor phase deposition (OVPD), chemical vacuum deposition (CVD) techniques, such as metalorganic chemical vapor deposition (MOCVD), plasma enhanced chemical vapor deposition (PECVD), evaporation, sublimation, electron cyclotron resonance-plasma enhanced vapor deposition (ECR-PECVD), and other thin film fabrication techniques, such as inkjet printing. Microelectronic device 102 may comprise a display device, such as an OLED, an LCD, an LED, a LEP, a portion of electronic signage using electrophoretic inks, an ED, a phosphorescent device a OLED, or some other material that is subject to degradation when exposed to contaminants, such as moisture, oxygen and chemicals. In many embodiments microelectronic device 102 comprises an organic material, such as an organic polymer.

In some embodiments, microelectronic device 102 comprises two or more layers of different materials. For example, in one embodiment, where microelectronic device 102 comprises an OLED pixel, microelectronic device 102 may comprise an anode layer (for example, Indium-Tin ion (ITO)), a hole injection layer, one or more organic emitters, an electron transport layer, and a cathode layer.

As mentioned above, substrate 104 may be rigid or flexible, serving as base for microelectronic device 102. Substrate 104 is typically formed from a transparent material, such as glass in rigid applications or one of a number of plastics in flexible applications, such as polyethylene terephthalate (PET), polyethylene naphthalate (PEN), polyimide (PI) and polyethylene (PE). The thickness of substrate 104 may vary from tens of nanometers to hundreds of nanometers or more. In the embodiment shown in FIG. 1, microelectronic device 102 and substrate 104 are encapsulated by two protective barrier layers, barrier layer 106 deposited onto microelectronic device 102 and barrier layer 108 deposited onto substrate 104. Each of the barrier layers prevent oxygen, moisture and other contaminants from contaminating microelectronic device 102. Barrier layer 106 protects microelectronic device 102 directly, while barrier layer 108 protects microelectronic device 102 in addition to the protection provided by flexible substrate 104, and therefore may be fabricated with somewhat lesser thicknesses and/or densities than barrier layer 108. In many cases, however, barrier layer 106 and 108 comprise the same structure and thickness.

Barrier layer 106 is typically desirable as an additional protectant, because water and oxygen generally penetrate plastic substrates easily, forming dark spots and edge shrinkages in microelectronic devices resulting in device degradation, light-output reduction and shortened device lifetime. These contaminants may also oxidize or corrode electrodes that connect microelectronic device 102 to driver circuitry.

The thickness of either barrier layer 106 or barrier layer 108 is typically about 10-100 nanometers, depending on the level of contaminant resistance needed for a particular application. In some embodiments, a barrier layer is formed of two or more layers of density gradients of the same material, as described later herein. The thickness of a barrier layer may depend on how many layers are used. In some embodiments, where microelectronic device 102 is highly impervious to contaminants, a single layer is all that may be needed. However, in applications where microelectronic device 102 is highly susceptible to contaminants, such as OLED devices, two or more layers may be needed. In general, one or two barrier layers provide sufficient barrier protection for some applications, while three or four barrier layers are needed for more sensitive devices. The most stringent applications may require five or more barrier layers.

Barrier layers 106 and 108 can each vary in thickness from several nanometers to a hundred nanometers or more, depending on moisture-protection requirements. In generally, a range from about 20 nm to 200 nm is used, and comprises one or more inorganic materials such as niobium oxide (NbOx), titanium oxide (TiOx), zinc oxide (ZnOx), aluminum oxide (Al₂O₃), silicon nitride (Si₃N₄), silicon dioxide SiO₂, or some other compounds known to provide contaminant protection to device 102. Thinner barrier layers may be used when the fabrication process or material used yields few defects, while thicker barrier layers may be needed when the fabrication process or material used yields many defects. In many embodiments, the material chosen for barrier layer 106 and/or 108 comprise transparent materials, as many applications are light-related, such as in OLED applications, LED applications, solar applications, etc.

One or both of the barrier layers shown in FIG. 1 are formed such that the density of a barrier layer varies as a function of its thickness, sometimes referred to herein as a “density gradient”. Varying the density may allow a barrier layer to flex along with substrate 104, in applications where a bendable product is desired. Allowing a barrier layer to flex may avoid or minimize cracking, thereby providing an improved layer of protection to device 102 from contaminants.

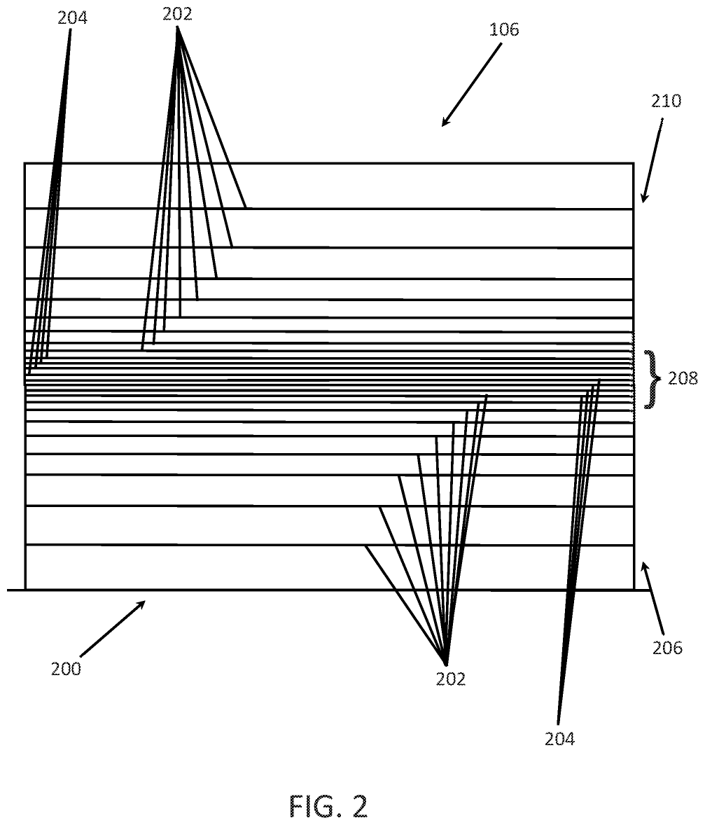

FIG. 2 is a microscopic, side view of one embodiment of one of the barrier layers shown in FIG. 1, such as barrier layer 106, deposited onto microelectronic device 102 at boundary 200. It should be understood that FIG. 2 represents only a portion of a width of barrier layer 106, i.e., the height of barrier layer 106 is not in proportion to its width as shown in FIG. 2. This view illustrates how the density of barrier layer 106 varies as a function of its thickness, in this embodiment, varying as a linear gradient, as shown by density lines 202 and 204. It should be understood that density lines 202 and 204 are for illustrative purposes only and typically cannot be seen on or in barrier layer 106, even microscopically. It should also be understood that although each of the density lines 202 and 204 represent a particular density, in general, the density of barrier layer 106 varies continuously. In other embodiments, the density varies in discrete amounts. Generally, density lines spaced closer together indicate a higher density than density lines spaced further apart from one another.

FIG. 2 shows how the density of barrier layer 106, in this embodiment, changes as a function of its thickness, beginning at a relatively low density at lower portion 206, increasing to a higher density at a middle portion 208, in this embodiment remaining at the higher density for a certain thickness (shown by density lines 204), then decreasing back down to a lower density at top portion 210. This “low-to-high-to-low” density gradient shown in FIG. 2 represents one “layer” of a barrier layer produced by one deposition “cycle”. Multiple layers may be used to fabricate a barrier layer when additional contaminant protection is desired, as described later herein.

The density of barrier layer 106 at lower portion 206 and top portion 210 need not be the same density. In this way, barrier layer 106 is able to flex upwards as well as downwards without cracking, as the less-dense material formed near bottom portion 206 and top portion 210 is more flexible than the more-dense material near middle portion 208 The higher-density middle portion 208 provides a high degree of moisture protection while the lower-density top and bottom portions provide more flexibility to a barrier layer.

The density of lower portion 206 and top portion 210 may be in a range from 60% to 85% of its crystal. while the density of middle portion 208 may be in a range between 85% and 100% of its crystal.

Using the low-to-high-to-low density gradient described above, barrier layer 106 may comprise a water vapor transmission rate (WVTR) of less than about 0.001 g/m²″day at 25° C. and 100% relative humidity.

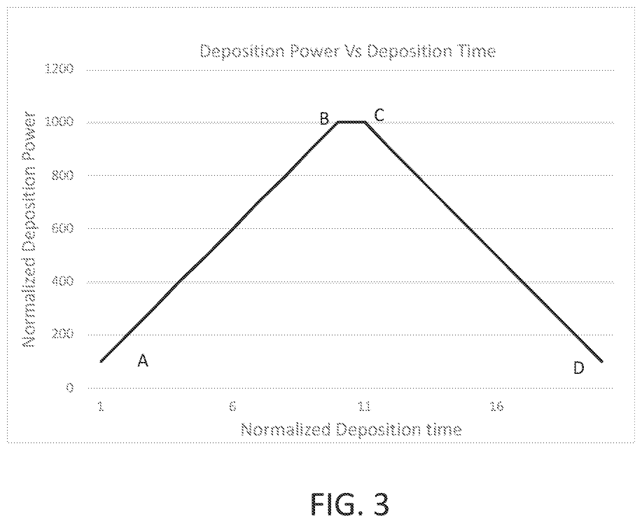

FIG. 3 is a graph showing one embodiment of a relationship between a deposition power delivered by thin film deposition equipment as the barrier layer of FIG. 2 is fabricated, and a time to fabricate the barrier layer, while the deposition processes occurs at a fixed deposition pressure. The deposition power generally relates to an amount of electrical power applied between an anode and a cathode in a deposition chamber. It may be expressed in terms of a power density, such as watts/cm². The term “power” and “power density” may be used interchangeable herein. The deposition power is commonly set to a value of anywhere between 100 w, and 1000 w, and the power density is typically a value of anywhere between 0.5 w/cm² to about 20 w/cm². The deposition pressure generally relates to a pressure maintained within a deposition chamber during the deposition process, generally between 3-50 mTorr.

It should be understood that while the density gradient of a barrier layer may change linearly, as shown in FIG. 3, in other embodiments, it may change in other ways. For example, the density could change non-linearly as a function of a barrier layer thickness, such as asymptotically, as a sinusoid, in discreet amounts, or in other ways.

The deposition process for fabricating a barrier layer in accordance with the principles herein comprises one or more variations to one or more of a number of thin film vacuum deposition processes, such as RF, pulsed DC or magnetron sputtering, vacuum thermal evaporation (VTE), organic vapor phase deposition (OVPD), chemical vacuum deposition (CVD) techniques, such as metalorganic chemical vapor deposition (MOCVD), plasma enhanced chemical vapor deposition (PECVD), evaporation, sublimation, electron cyclotron resonance-plasma enhanced vapor deposition (ECR-PECVD), and combinations thereof. In such techniques, a barrier layer is deposited as a thin layer of protective material, on the order of nanometers, onto substrate 104 or device 102 using specialized deposition equipment well-known in the art. Suitable barrier materials comprise one or more inorganic materials, such as metals, metal oxides, metal nitrides, metal carbides, metal oxynitrides, metal oxyborides, and combinations thereof, for example NbOx, TiOx, ZnOx, Al₂O₃, Si₃N₄ and SiO₂.

In the graph shown in FIG. 3, a deposition power is changed during fabrication of a barrier layer in a deposition chamber having a fixed pressure, such as 5 mTorr, 10 mTorr, 15 mTorr etc., in order to achieve a varying density of barrier layer 106. For example, if magnetron sputtering is used, the deposition power may be varied from 100 w to several thousand watts, depending on a target size used, and may be expressed in terms of a target power density, such as from 0.2 w/cm² to 20 w/cm². For oxides and nitrides, a small, fixed, partial pressure of argon, oxygen or nitrogen may be introduced into a deposition chamber to ensure thin film stoichiometry. A deposition power speed may be defined as a highest deposition power used minus a lowest deposition power used, divided by a time to complete the low-to-high-to-low cycle. The deposition power speed can be used to change different thin film properties of a barrier layer, such as a thin film density and thin film refractive index. By changing the deposition time, different barrier layer thicknesses can be achieved.

In FIG. 3, the axes of deposition power and deposition time are shown as normalized variables, so the units shown are intended to show relative units and not actual values of deposition power and deposition time. In this example, the deposition power varies linearly as a function of deposition time, beginning at a deposition power of about 100, shown as point “A” in FIG. 3, and increases over time to about 1,000, as shown as point “B”, or about ten times the deposition power at the start of deposition, in this example, over a normalized time of about 9. The power may then be held constant at 1,000 for a time of about 2, as shown as point “C”, before decreasing linearly to a power of about 100, as shown as point “D”. It should be understood that in other embodiments, the deposition power does not “plateau” for a time between points “B” and “C” but, rather, immediately begins descending once the peak power at point “B” is reached. It should also be understood that in other embodiments, the steady deposition power between points “B” and “C” may be greater or less than the time indicated between points “B” and “C” in FIG. 3, resulting in a middle portion 208 having a uniform density that is either thicker, or thinner, than the density depicted in middle portion 208 as shown in FIG. 2.

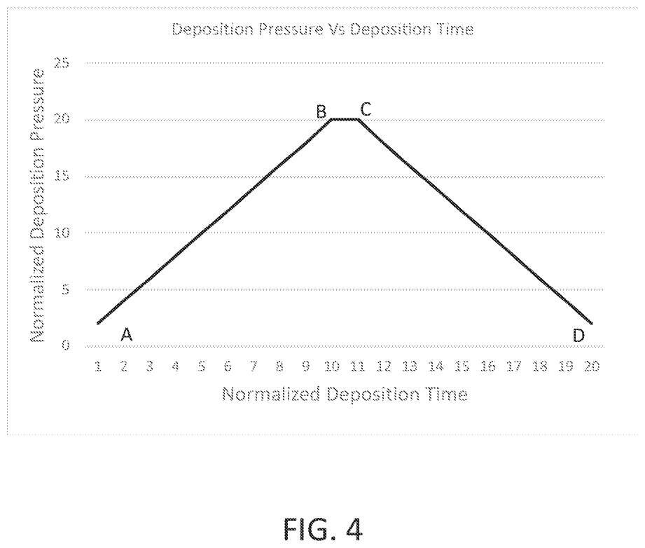

FIG. 4 is a graph showing a relationship between a deposition pressure in a deposition chamber as barrier layer 106 shown in FIG. 2 is fabricated, and a time to fabricate barrier layer 106, while the deposition processes occurs at a fixed deposition power.

In this embodiment, a deposition pressure is changed during fabrication of a barrier layer in order to achieve a varying density of barrier layer 106, while a deposition power is held constant. As the deposition chamber pressure increases, the density of material deposited during fabrication increases, and vice-versa. In one embodiment, the deposition pressure may vary from 5 mTorr to 25 mTorr and back to 5 mTorr, at a fixed deposition power of 500 w over a 2 hour deposition time in order to achieve the density gradient of barrier layer 106 as shown in FIG. 2.

A deposition pressure speed may be defined as a highest deposition pressure used minus a lowest deposition pressure used, divided by a time to complete the low-to-high-to-low cycle. The deposition pressure speed can be used to change different thin film properties of a barrier layer, such as a thin film density and a thin film refractive index. By changing the deposition time, different barrier layer thicknesses can be achieved.

In FIG. 4, the axes of deposition pressure and deposition time are shown as normalized variables, so the units shown are intended to show relative units and not actual values of deposition pressure and deposition time. In this example, the deposition pressure varies linearly as a function of deposition time, beginning at a deposition pressure of about 2, shown as point “A” in FIG. 4, and increasing linearly over time to about 20, as shown as point “B”. The pressure is then be held constant at 20 for a time of about 2, as shown as point “C”, before decreasing linearly to a pressure of about 2, as shown as point “D”. It should be understood that in other embodiments, the deposition pressure does not “plateau” for a time between points “B” and “C” but, rather, immediately begins descending once the peak pressure at point “B” is reached. It should also be understood that in other embodiments, the steady deposition pressure between points “B” and “C” may be greater or less than the time indicated between points “B” and “C” in FIG. 4, resulting in a middle portion 208 having a uniform density that is either thicker, or thinner, than the density depicted in middle portion 208 as shown in FIG. 2.

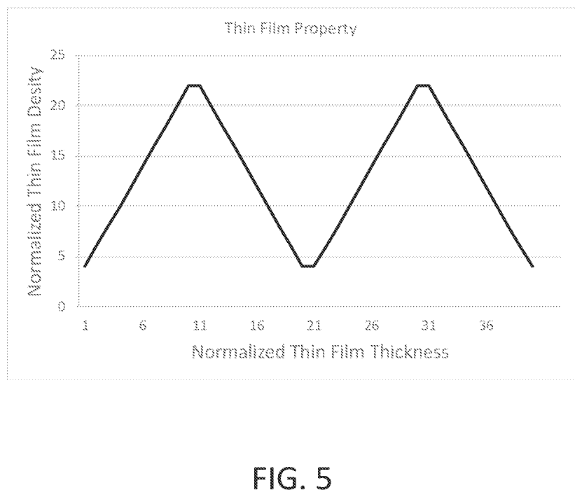

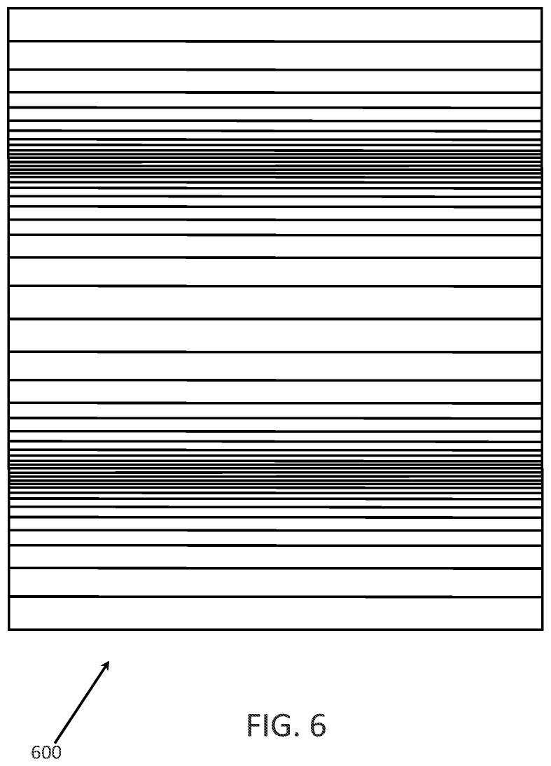

FIG. 5 is a graph showing how the density of barrier layer 106 or 108, in one embodiment, varies as a function of its thickness. In this embodiment, a barrier layer is fabricated using two low-to-high-to-low (sometimes referred to herein as “low-high-low”) deposition cycles (either at a fixed deposition pressure and varying deposition power, or at a fixed deposition power and varying deposition pressure), resulting in a barrier layer whose density varies from low-to-high-to-low and again from low-to-high-to-low as a function of the barrier layer's thickness, as shown in FIG. 6. FIG. 6 is similar to FIG. 2, in that it illustrates a barrier layer 600 with density lines showing the density gradient, that FIG. 6 represents only a portion of a width of barrier layer 600, i.e., the height of barrier layer 600 is not in proportion to its width as shown in FIG. 6, that the density lines are for illustrative purposes only and cannot be seen, that the density of barrier layer 600, generally, varies continuously, and that density lines spaced closer together indicate a higher density than density lines spaced further apart from one another. FIG. 6 is a microscopic, side view of barrier layer 600 in an embodiment where the density of barrier layer 106 or 108 varies as a series of low-to-high-to-low transitions, i.e., a repetition of the densities of barrier layer 106 or 108 as shown in FIG. 2. Each low-to-high-to-low density transition may be thought of as a “layer”, and a plurality of layers may be fabricated on top of one another in embodiments where greater protection of microelectronic device 102 is needed. The use of two or more layers may reduce a WVTR to between 0.1 g/m²/day to 10⁻⁶ g/m²/day.

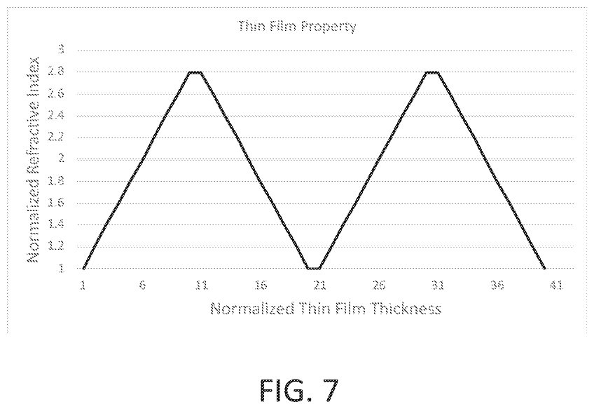

FIG. 7 is a graph showing how a thin film refractive index of barrier layer 106 or 108 varies as a function of its thickness in accordance with FIGS. 5 and 6, showing the refractive index as a result of two low-high-low deposition cycles (either at a fixed deposition pressure and varying deposition power, or at a fixed deposition power and varying deposition pressure). As in other graphs herein, the axes have been normalized. The refractive index of a barrier layer generally varies as a function of its density. The thin film refractive index of a barrier layer is an important parameter for controlling the density of barrier layer 106 or 108 during the manufacturing process. Generally, thin film refractive index and density relationship will follow (n−1)/d=CM^{-u} and (n²−1)/(n²+2)d=KM^{-v} where d is density, n is refractive index, C and K are constants, the exponents u and v are approximately equal to 0.4, and M is the averaged atomic mass of a substance. By monitoring of the refractive index using known ellipsometry techniques, the density of barrier layer 106 and 108 can be precisely controlled during fabrication. Thus, monitoring the refractive index during fabrication provides a way to precisely control the density of barrier layer 106 or 108 as a function of its thickness.

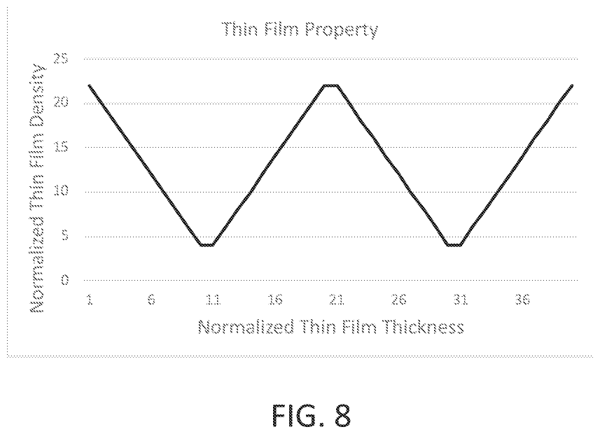

FIG. 8 is a graph showing how the density of barrier layer 106 or 108, in another embodiment, varies as a function of its thickness. In this embodiment, a barrier layer is fabricated using two high-to-low-to-high deposition cycles, resulting in a barrier layer having a density that varies from high-to-low-to-high and again from high-to-low-to-high as a function of the barrier layer's thickness. Similarly, a barrier layer fabricated as taught in this embodiment comprises a refractive index that varies in accordance with its density as a function of thickness. When graphed, such a refractive index would have a similar form to the graph shown in FIG. 8.

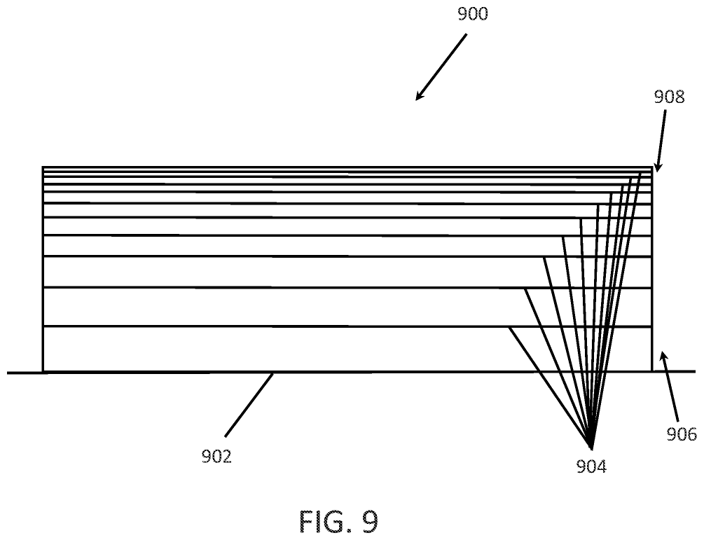

FIG. 9 is a microscopic, side view of another embodiment of one of the barrier layers shown in FIG. 1, shown as barrier layer 900, in this example contacting microelectronic device 102 at boundary 902. It should be understood that FIG. 9 represents only a portion of a width of barrier layer 900, i.e., the height of barrier layer 900 is not in proportion to its width as shown in FIG. 9. The density of barrier layer 900 varies as a function of its thickness, in this embodiment, varying as a linear gradient, as shown by density lines 904. It should be understood that density lines 904 are for illustrative purposes only and are not visible on or within barrier layer 900. It should also be understood that although each of the density lines 904 represent a particular density, in general, the density of barrier layer 900 varies continuously.

FIG. 9 shows how the density of barrier layer 900, in this embodiment, changes linearly as a function of its thickness, beginning at a relatively low density at lower portion 906 and increasing to a higher density near top portion 908. The density of barrier layer 900, in this embodiment, is formed by varying either a deposition power, as shown in FIG. 3, or varying a deposition pressure, as shown in FIG. 4, from point A to point B in both figures, as a result of a linear increase in power or pressure, respectively. In another embodiment, the density gradient could be reversed, with a relatively high density near bottom portion 9 decreasing to a lower density at top portion 908. In the embodiment shown in FIG. 9, barrier layer 900 is best able to flex downwardly without cracking (i.e., outer edges flexing toward device 102, where the density is high near the boundary of microelectronic device 102), as the less-dense material formed near bottom portion 906 is more flexible than the more-dense material near top portion 908. As in the embodiment shown in FIG. 2, the density of lower portion 906 may be in a range from 60-85% of its crystal, while the density of top portion 908 may be in a range between 85-100% to its crystal. The advantage of using only a low-to-high density gradient, as shown, vs. a density gradient from low-to-high-to-low, as shown in FIG. 2, is that less material is used in this embodiment and, also, that encapsulated electronic device 100 can be made faster.

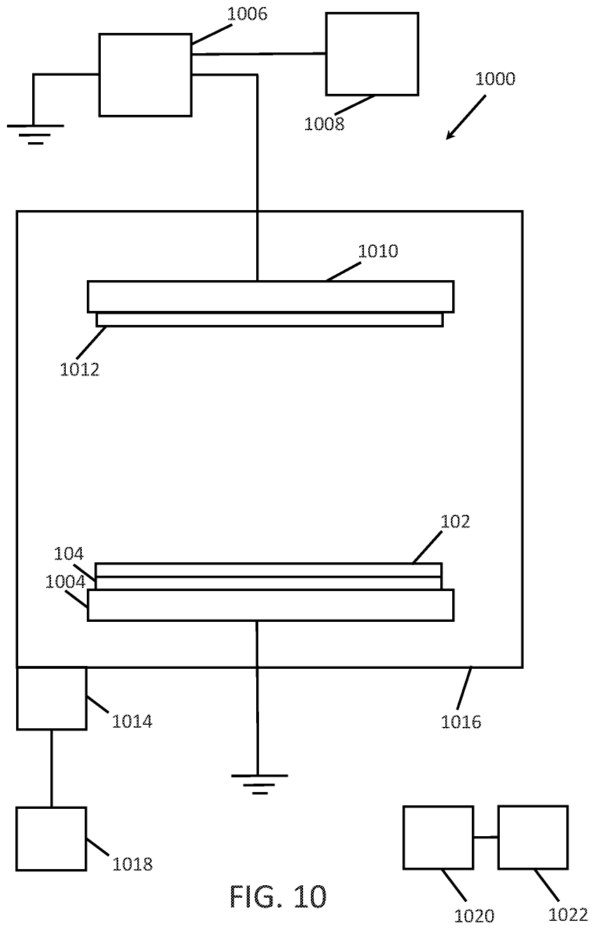

FIG. 10 is block diagram of one embodiment of vapor deposition equipment 1000, for fabricating at least barrier layer 106 onto microelectronic device 102 or barrier layer 108 onto substrate 104 using a physical vapor deposition technique. The components of deposition equipment 1000 are well-known in the art. For example, Vapor Technologies, Inc. of Longmont, Colo. sells a wide variety of PVD and CVD equipment. The components of vapor deposition equipment 1000 are controlled by one or more processors 1020 coupled to one or more memories 1022.

Shown in FIG. 10 is substrate 104 resting on anode 1002. Microelectronic device 102 has already been deposited onto substrate 104. A deposition power generator 1006, controlled by a power controller 1008, is coupled to cathode 1010, and a target material 1012 is attached to cathode 1010. Air is evacuated from deposition chamber using pump 1016, then back-filled with a high-purity, inert gas such as Argon and pressurized either at a constant pressure, or at varying pressures, during the time required to form barrier layer 106 or barrier layer 108, herein referred to as the “deposition time”. The pressure delivered by pump 1016 may deliver anywhere from 0.5 mTorr to 100 mTorr during the deposition process and controlled by pressure controller 1018.

During the deposition process, deposition power generator 1006 is energized, either at a constant DC voltage, a pulsed voltage, a voltage that varies as an RF signal, or some other fixed or variable voltage, by power controller 1008. The voltage is applied across cathode 1010 and anode 1004 at a voltage of up to 10 k volts at a “deposition power” expressed in watts per area of microelectronic device 102. The deposition power is either fixed or varied, depending on which embodiment of the invention is being utilized. The voltage applied to cathode 1010 and anode 1004 causes the inert gas to ionize, and then be attracted forcefully to target 1012. Target 1012 is usually an inorganic material such as niobium oxide (NbOx), titanium oxide (TiOx), zinc oxide (ZnOx), aluminum oxide (Al₂O₃), silicon nitride (Si₃N₄), silicon dioxide SiO₂, or some other known chemical compounds that can provide protection to device 102 from oxygen, moisture and other contaminants.

The ionized gas bombards target 1012, causing target atoms to be ejected from target 1012 to anode 1004, where they form on microelectronic device 102 as barrier layer 106. During this deposition time, either the power or power density is varied by power controller 1008, of the pressure is varied by pressure controller 1018. In some embodiments, the power, power density or the pressure is varied continuously from low, to high, to low, forming one “density layer” of barrier layer 106. In some embodiments, multiple layers are used, depending on how much moisture/oxygen/environmental protection is desired for microelectronic device 102.

It should be understood that although the above description represents deposition equipment related to physical vapor deposition, other embodiments could utilize well-known chemical vapor deposition equipment.

The one or more processors 1020 comprise one or more general or specific-purpose microprocessors, microcontrollers and/or custom ASICs, and/or discrete components able to fabricate barrier layers. The one or more processors 1020 may be selected based on processing capabilities, power-consumption properties, cost and/or size considerations. Processor 1020 is coupled to one or more non-transitory memories 1022 that store processor-executable instructions used by the one or more processors 1020 to perform one or more methods for fabricating barrier layers. Examples of the one or more memories include RAM, ROM, hard drives, flash memory, EEPROMs, or virtually any other type of electronic, optical, or mechanical memory device, excluding propagated signals.

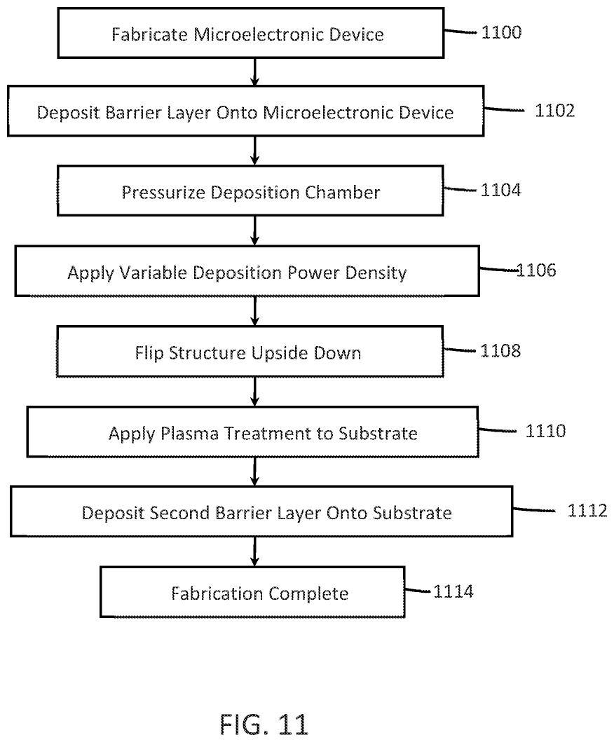

FIG. 11 is a flow chart illustrating one embodiment of a method for fabricating an encapsulated microelectronic device as shown in FIG. 1 by thin film equipment as shown in FIG. 10. In this embodiment, barrier layer 106 comprises two “low-high-low” density layers, as shown in FIG. 6, while barrier layer 108 comprises only one “low-high-low” density layer, as shown in FIG. 2. While reference is made in this embodiment to a physical vapor deposition process, it should be understood that the concepts descried subsequently may be applied to a chemical vapor deposition process.

At block 1100, microelectronic device 102 is fabricated onto substrate 104 inside a deposition chamber, in some embodiments deposition chamber 1016, using one or more variations of thin film fabrication methods well known in the art, such as by a modified process of physical vapor deposition (PVD), i.e., sputtering or evaporation techniques, or by a modified process of chemical vaporization techniques. The modified techniques are discussed herein.

At block 1102, barrier layer 106 is deposited onto microelectronic device 102 as follows:

At block 1104, in one embodiment, the air inside deposition chamber 1016 is evacuated by pressure controller 1018 controlling pump 1014, and then pressure controller 1018 causes pump 1014 to pressurized deposition chamber 1016 with a gas, such as argon, nitrogen or oxygen at a predetermined, fixed pressure such as at a pressure between 1 mTorr and 100 mTorr, for example, 15 mTorr.

At block 1106, a variable voltage/deposition power density is delivered by deposition power generator 1006 under control of power controller 1008 between cathode 1010 and anode 1004. In one embodiment, the voltage is varied linearly at a rate approximately equal to a highest voltage to be used minus a lowest voltage to be used, divided by a disposition time of barrier layer 106. For example, if the highest voltage used is 6 kv, the lowest voltage used is 2 kv, and the deposition time is 60 minutes, the rate of change of the voltage applied between cathode 1010 and anode 1004 is (6 k−4 k)/60 min= 1/30 kilovolts per minute or a rate of change of 33.33 volts per minute. The voltage applied across cathode 1010 and anode 1004, and a related current, may be expressed as a deposition power, or more accurately, a deposition power density, expressed as watts of power delivered by deposition power generator 1006 divided by an area of target 1012. Generally, the deposition power density varies as a function of the voltage applied across cathode 1010 and anode 1004.

As barrier layer 106 is created during the deposition time, its density varies as a function of its thickness as the applied deposition power density changes over the deposition time, as the deposition pressure is held constant. For example, the density of barrier layer 106 may vary as shown in FIG. 5 as the deposition power density changes linearly from a low power density, to a higher power density, pausing at the higher power density for a predetermined time period, then back down to a low power density (either the same or different than the first, low power density), then repeated. As the voltage and associated deposition power density increases, more atoms are expelled from target 1012, allowing a greater number of atoms to form onto the emerging barrier layer 106, resulting in increased density. When the voltage and associated deposition power density falls, less atoms are expelled from target 1012, and the density of barrier 106 falls in tandem.

If power controller 1008 holds the voltage/deposition power density at a constant level for a predetermined time period, as shown in FIG. 5, it will create a portion of barrier layer 106 that is of uniform density. This is best shown in FIG. 3, between points “B” and “C”, where the deposition power is uniform for a normalized time period of about 2 units at a normalized level of 1,000. The thickness of the uniform density portion can be changed by holding the voltage/deposition power density at a constant level for a shorter or a longer amount of time than what is shown in FIG. 3, resulting in a thinner, or thicker, layer of uniform density, respectively.

In this example, barrier layer 106 is complete when power controller 1008 has cycled the voltage/deposition power two times, each cycle varying the voltage/deposition power from low-to-high-to-low.

At block 1108, in one embodiment, substrate 104, microelectronic device 102 and barrier layer 106, now together as a single unit, is flipped upside down, exposing substrate 104 to target 1012, which may comprise the same material as used to form barrier layer 106, or a different material.

At block 1110, in one embodiment, the exposed surface of substrate 104 may be plasma treated, as well-known in the art, in order to prepare substrate 104 for the application of barrier layer 108.

At block 1112, barrier layer 108 is formed onto substrate 104 in a similar manner as described above. It should be understood that the deposition time, voltage/deposition power density rate of change, and density gradient may be the same, or different, than the deposition time, voltage/deposition power density rate of change, and density gradient of barrier layer 106. For example, the voltage/deposition power density could increase linearly to deposit material from target 1012 as shown in FIG. 9, or to form a density gradient as shown in FIG. 2, showing one “cycle”. Other profiles can be generated by varying the voltage/deposition power density accordingly.

At block 1114, the process ends, with encapsulated electronic device 100 completed.

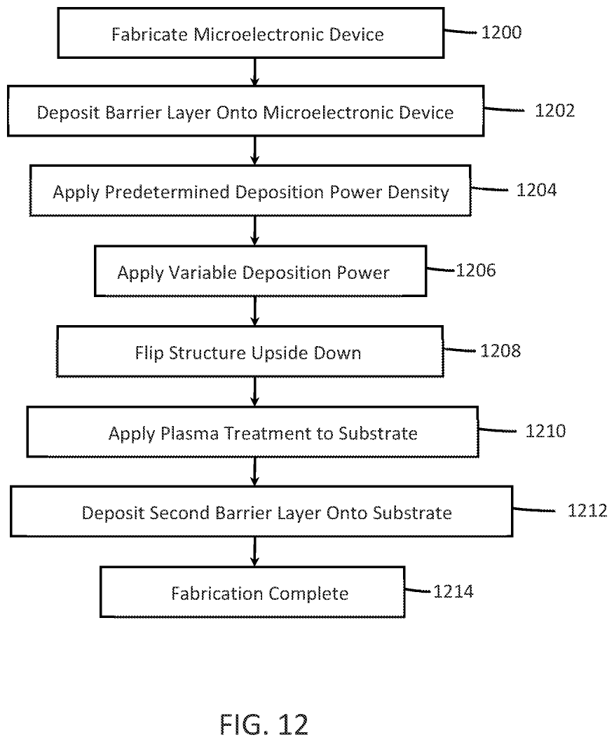

FIG. 12 is a flow chart illustrating another embodiment of a method for fabricating encapsulated electronic device 100 as shown in FIG. 1 by thin film equipment as shown in FIG. 10. In this embodiment, barrier layer 106 comprises two “low-high-low” density layers, as shown in FIG. 6, while barrier layer 108 comprises only one “low-high-low” density layer, as shown in FIG. 2.

At block 1200, microelectronic device 102 is fabricated onto substrate 104 inside a deposition chamber, in some embodiments deposition chamber 1016 using one or more variations of thin film fabrication methods well known in the art, such as a modified physical vapor deposition (PVD) technique, i.e., sputtering or evaporation, or by one or more modified chemical vaporization techniques. The modified techniques are discussed herein.

At block 1202, barrier layer 106 is deposited onto microelectronic device 102 as follows:

At block 1204, in one embodiment, a constant voltage/deposition power density is applied to cathode 1012 and anode 1004 by deposition power generator 1006 via power controller 1008, at a voltage of between 1 kv and 50 kv, such as 4 kv.

At block 1206, in one embodiment, the air inside deposition chamber 1016 is evacuated by pressure controller 1018 controlling pump 1014, and then pressure controller 1018 causes pump 1014 to pressurized deposition chamber 1016 with a gas, such as argon, nitrogen or oxygen over a range of pressures during the deposition time, for example between 1 mTorr and 50 mTorr over a 2 hour period in accordance with a variable pressure profile, such as the one shown in FIG. 4. In this embodiment, the deposition pressure changes linearly from a low pressure, to a higher pressure, pausing at the higher pressure for a predetermined time period, then back down to a low pressure (either the same or different than the first, low pressure), then repeated. In one embodiment, the deposition pressure is varied linearly at a rate approximately equal to a highest pressure to be used minus a lowest pressure to be used, divided by the disposition time. For example, if the highest deposition pressure used is 40 mTorr, the lowest deposition pressure used is 2 mTorr, and the deposition time is 120 minutes, the rate of change of the deposition pressure inside deposition chamber 1016 is (40-2)/120=19/60 mTorr per hour, or 0.317 mTorr per minute.

As barrier layer 106 is created during the deposition time, its density varies as a function of the deposition pressure, in one embodiment, linearly, as the deposition voltage/deposition power density is held constant. For example, the density of barrier layer 106 may vary as shown in FIG. 5 as the deposition pressure is varied during the deposition time. As the deposition pressure increases, more atoms are expelled from target 1012, allowing a greater number of atoms to form onto the emerging barrier layer 106, resulting in increased density. When the deposition pressure falls, less atoms are expelled from target 1012, and the density of barrier 106 falls in tandem.

In one embodiment, pressure controller 1018 may hold the deposition pressure at a constant level for a period of time, in order to create a portion of barrier layer 106 that is of uniform density. This is best shown in FIG. 4, between points “B” and “C”, where the deposition pressure is uniform for a normalized time period of about 2 units at a normalized deposition pressure level of 20 units. The result is a portion of barrier layer 106 having a uniform density. The thickness of the uniform density portion can be changed by holding the deposition pressure at a constant level for a shorter or a longer amount of time than what is shown in FIG. 4, resulting in a thinner, or thicker, layer of uniform density, respectively.

In this example, barrier layer 106 is complete when pressure controller 1018 has cycled the deposition power two times, each cycle varying the deposition pressure from from low-to-high-to-low.

At block 1208, substrate 104, microelectronic device 102 and barrier layer 106, now together as a single unit, is flipped upside down, exposing substrate 104 to target 1012, which may comprise the same material as used to form barrier layer 106, or a different material.

At block 1210, the exposed surface of substrate 104 may be plasma treated, in order to prepare substrate 104 for the application of barrier layer 108.

At block 1212, barrier layer 108 is formed onto substrate 104 in a similar manner as described above. It should be understood that the deposition time, pressure rate of change, and density gradient may be the same, or different, than the deposition time, pressure rate of change, and density gradient of barrier layer 106. For example, the deposition pressure could increase linearly to deposit material from target 1012 as shown in FIG. 9, or form a density gradient as shown in FIG. 2, showing one “cycle”. Other profiles can be generated by varying the deposition pressure accordingly.

At block 1214, the process ends, with encapsulated electronic device 100 completed.

The methods or algorithms described in connection with the embodiments disclosed herein may be embodied directly in hardware or embodied in processor-readable instructions executed by a processor. The processor-readable instructions may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components.

Accordingly, an embodiment of the invention may comprise a computer-readable media embodying code or processor-readable instructions to implement the teachings, methods, processes, algorithms, steps and/or functions disclosed herein.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

We claim:

1. An encapsulated electronic device, comprising:
a flexible substrate;
a microelectronic device fabricated onto a first surface of the flexible substrate; and
a protective barrier layer fabricated onto the microelectronic device for preventing contamination of the microelectronic device, the protective barrier layer comprising a density that varies as a function of a thickness of the protective barrier layer.

2. The encapsulated microelectronic device of claim 1, further comprising:
a second protective barrier layer fabricated onto a second, opposing surface of the flexible substrate for preventing contamination of the microelectronic device through the flexible substrate, the second barrier layer comprising a second density that varies as a function of a thickness of the second protective barrier layer.

3. The encapsulated microelectronic device of claim 1, wherein the density of the protective barrier layer varies continuously from a low density in a lower portion of the protective barrier layer adjacent to the microelectronic device, to a high density in a middle portion of the protective barrier layer, to a second low density in a top portion of the protective barrier layer exposed to ambient air.

4. The encapsulated microelectronic device of claim 3, wherein the low density comprises a density from about X to Y.

5. The encapsulated microelectronic device of claim 3, wherein the high density comprises a density from about X to Y.

6. The encapsulated microelectronic device of claim 1, wherein the density of the protective barrier layer varies as a series of low-to-high-to-low transitions.

7. The encapsulated microelectronic device of claim 1, wherein the density of the protective barrier layer varies linearly as a gradient.

8. The encapsulated microelectronic device of claim 1, wherein the protective barrier layer comprises an inorganic, transparent material, selected from the group consisting of Al₂O₃, SiO₂, Si₂N₄, and Nb₂O₅.

9. The encapsulated microelectronic device of claim 1, wherein the protective barrier layer comprises a refractive index that varies as a function of the density of the protective barrier layer.

10. The encapsulated microelectronic device of claim 1, wherein the protective barrier layer comprises a thickness of about between 20 nanometers and 200 nanometers.

11. A method for fabricating an encapsulated microelectronic device, comprising:
fabricating the microelectronic device onto a flexible substrate; and
fabricating a protective barrier layer onto the microelectronic device, comprising:
varying a deposition power density delivered by a deposition power generator over a deposition time while maintaining a constant deposition pressure of a deposition chamber, resulting in the protective barrier layer having a density that varies as a function of its thickness.

12. The method of claim 11, further comprising:
fabricating a second protective barrier layer onto the flexible substrate, comprising:
varying the deposition power density delivered by the deposition power generator over a second deposition time while maintaining the constant deposition pressure of the deposition chamber, resulting in the second protective barrier layer having a density that varies as a function of its thickness.

13. The method of claim 11, wherein varying a deposition power density of the deposition power generator over a deposition time comprises:
varying a power density delivered by the deposition power generator continuously from a low power density to a high power density then down to a second low power density during the deposition time.

14. The method of claim 13, wherein the high power density comprises a power density of about 20 w/cm².

15. The method of claim 11, wherein varying a deposition power density delivered by the deposition power generator over a deposition time comprises:
varying a power density delivered by the thin film power generator from about 0.5 w/cm² to about 20 w/cm².

16. The method of claim 11, wherein varying a deposition power density over a deposition time comprises:
repeatedly varying a power density delivered by the deposition power generator continuously from a low power density to a high power density then down to second low power density during the deposition time.

17. A method for fabricating an encapsulated microelectronic device, comprising:
fabricating the microelectronic device onto a flexible substrate; and
fabricating a protective barrier layer onto the microelectronic device, comprising:
varying a deposition pressure of a deposition chamber over a deposition time while maintaining a constant deposition power density delivered by a deposition power generator, resulting in the protective barrier layer having a density that varies as a function of its thickness.

18. The method of claim 17, further comprising:
fabricating a second protective barrier layer onto the flexible substrate, comprising:
varying the deposition pressure of the deposition chamber over a second deposition time while maintaining the constant deposition power density delivered by the deposition power generator, resulting in the second protective barrier layer having a density that varies as a function of its thickness.

19. The method of claim 17, wherein varying a deposition pressure of a deposition chamber over a deposition time comprises:
varying the deposition pressure of the deposition chamber continuously from a low pressure to a high pressure then down to a second low pressure during the deposition time.

20. The method of claim 17, wherein varying a deposition pressure of a deposition chamber over a deposition time comprises:
repeatedly varying the deposition pressure of the deposition chamber continuously from a low pressure to a high pressure then down to a second low pressure during the deposition time.
